(19) United States
(12) Patent Application Publication
(10) Pub. No.: US 2007/0243313 A1
(43) Pub. Date: Oct. 18, 2007

(54) Method of manufacturing radiographic image conversion panel

(75) Inventor: Ken Hasegawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/237,962

(22) Filed: Sep. 29, 2005

(30) Foreign Application Priority Data
Sep. 30, 2004 (JP) 2004-287467

(51) Int. Cl. C23C 16/52; B05D 3/02; B05D 3/00; C23C 16/00

(52) U.S. Cl. 427/8; 427/372.2; 427/561; 427/585; 427/592

(57) ABSTRACT

There is provided a method of manufacturing a radiation image conversion panel in which a stimulable phosphor layer is formed on a substrate by performing film deposition through vacuum evaporation. The thickness of the stimulable phosphor layer is measured during the film deposition with a layer thickness measurement device or devices to obtain layer thickness measurements, and heating of the film forming material is controlled based on the thus obtained layer thickness measurements. Thus, film deposition can be performed at a proper vapor deposition rate to form a stimulable phosphor layer having an accurate thickness.

### BACKGROUND OF THE INVENTION

The present invention relates to a method of manufacturing a radiographic image conversion panel through vacuum evaporation. More specifically, the present invention relates to a method of manufacturing a radiographic image conversion panel which allows a radiographic image conversion panel that has a stimulable phosphor layer having a proper thickness to be manufactured in a consistent manner.

There are known a class of phosphors which accumulate a portion of applied radiations (e.g. x-rays, α-rays, β-rays, γ-rays, electron beams, and uv (ultraviolet) radiation) and which, upon stimulation by exciting light such as visible light, give off a burst of light emission in proportion to the accumulated energy. Such phosphors called stimulable phosphors are employed in medical and various other applications.

An exemplary application is a radiographic image information recording and reproducing system which employs a radiographic image conversion panel having a layer made of the stimulable phosphor (hereinafter referred to simply as a “phosphor layer”). The radiographic image conversion panel is hereinafter simply referred to as the “conversion panel” and is also called “stimulable phosphor panel (sheet)”. This system has already been commercialized as FCR (Fuji Computed Radiography) from Fuji Photo Film Co., Ltd.

In that system, radiographic image information about a subject such as a human body is recorded on the conversion panel (more specifically, the phosphor layer). After the radiographic image information is thus recorded, the conversion panel is irradiated with exciting light to produce photostimulated luminescence which, in turn, is read photoelectrically to yield an image signal. Then, an image reproduced on the basis of the read image signal is output as the radiographic image of the subject, typically to a display device such as CRT or on a recording material such as a photographic material.

The conversion panel is typically produced by the steps of first preparing a coating solution having the particles of a stimulable phosphor dispersed in a solvent containing a binder, etc., applying the coating solution to a support in sheet form that is made of glass or resin, and drying the applied coating.

Conversion panels are also known that are made by forming a phosphor layer on a support through methods of physical vapor deposition (vapor deposition) such as vacuum evaporation as described in JP 2789194 B and JP 5-249299 A. The phosphor layer prepared by the vapor deposition has excellent characteristics. First, it contains less impurities since it is formed under vacuum; further, it is substantially free of any substances other than the stimulable phosphor, as exemplified by the binder, so it has high uniformity in performance and still assures very high luminous efficiency.

In a conversion panel, it is important that the thickness of a phosphor layer be appropriate.

If the thickness of the phosphor layer is not appropriate, the interval between a sensor for reading photostimulated luminescence and a phosphor layer surface becomes inappropriate, which causes the degradation of image quality, such as blurring or distortion of an image. Such degradation in image quality is a serious problem that may cause misdiagnosis in the medical application as in the above-mentioned FCR. Therefore, a very high degree of accuracy is required for the phosphor layer of the conversion panel to have an appropriate thickness.

Typically, in vacuum evaporation, the vapor deposition rate is controlled and film deposition is carried out only for a period of time determined by the vapor deposition rate, thereby obtaining a thin film having a predetermined thickness. For example, JP 2001-115260 A discloses a method involving measuring transmitted light or reflected light of a film, and controlling the heating in accordance with measurements, thereby controlling the vapor deposition rate. Furthermore, JP 2004-91858 A discloses a method involving measuring the pressure in a film forming system, and controlling the heating in accordance with measurements to control the vapor deposition rate.

Furthermore, known as an apparatus for manufacturing a conversion panel which includes a phosphor layer formed by vacuum evaporation is an apparatus as disclosed by JP 2004-76074 A with which a conversion panel having an appropriate thickness is manufactured by detecting the evaporation amount of each film forming material with a sensor making use of a quartz oscillator, and controlling the vapor deposition rate using detection results.

According to the above-mentioned film forming method, the pressure, optical characteristics of a film, evaporation amount of each film forming material, and the like are measured, and the vapor deposition rate is presumed from the measurements, whereby control is performed. Therefore, the vapor deposition rate may have an error. In particular, in the case where measurement data is influenced in some ways, an error is caused in the vapor deposition rate.

Furthermore, a phosphor layer formed by vacuum evaporation has pores formed therein owing to its columnar crystal structure, so that it is difficult to exactly measure transmitted light, reflected light, and the like. Furthermore, for the same reason, it is also difficult to presume the vapor evaporation amount (thickness) from the evaporation amount of each film forming material, pressure in a system, optical characteristics, and the like. Therefore, it is difficult to exactly presume the vapor deposition rate in forming a phosphor layer by vacuum evaporation.

A phosphor layer formed by vacuum evaporation usually has a thickness of about 500 μm, and may often have a larger thickness of more than 1,000 μm. Therefore, when the presumed vapor deposition rate has an error, a large error in thickness may occur.

### SUMMARY OF THE INVENTION

An object of the present invention is to solve the above-mentioned problems of the prior art, and to provide a method of manufacturing a radiographic image conversion panel having a stimulable phosphor layer formed by vacuum evaporation, in which the layer thickness is directly measured to control the vapor deposition rate with a high degree of accuracy, and film deposition can be exactly ended when the stimulable phosphor layer with a predetermined thickness is formed, without relying on the control by the time presumed from the vapor deposition rate.

In order to achieve the above object, the present invention provides a method of manufacturing a radiation image conversion panel, comprising: forming a stimulable phosphor layer on a substrate by performing film deposition through vacuum evaporation; measuring a thickness of the stimulable phosphor layer during the film deposition with layer thickness measurement means to obtain layer thickness measurements; and controlling heating of film forming material based on the thus obtained layer thickness measurements.

In the method of manufacturing a radiation image conversion panel of the present invention, it is preferable that the layer thickness measurement means comprises a laser displacement sensor.

Further, it is preferable that the layer thickness measurements measured by the layer thickness measurement means is differentiated with respect to time to calculate a vacuum evaporation rate, and then the heating of the film forming material is controlled using the thus calculated vacuum evaporation rate.

Further, it is preferable that a look-up table representing a relationship between heating temperatures and vacuum evaporation rates is previously prepared, a heating temperature is determined from the calculated vacuum evaporation rate using the thus prepared look-up table, and the heating of the film forming material is controlled in accordance with the thus determined heating temperature.

Further, it is preferable that the film deposition through the vacuum evaporation is performed by containing the film forming material in plural vessels for film forming material.

Further, it is preferable that the film forming material comprises a base film forming material constituting a base component of a stimulable phosphor and an activator film forming material constituting an activator component of the stimulable phosphor, the plural vessels include at least one first vessel which contains the base film forming material and at least one second vessel which contains the activator film forming material, and the base film forming material contained in at least one first vessel and the activator film forming material contained in at least one second vessel are heated and evaporated.

Further, it is preferable that the thickness of the stimulable phosphor layer is measured by using plural layer thickness measurement means.

Further, it is preferable that the heating of the film forming material in one vessel for film forming material is controlled based on thickness measurements obtained by one of the plural layer thickness measurement means.

Further, it is preferable that the plural vessels for film forming material are arranged in one direction, and the film deposition is performed while the substrate is linearly conveyed in a to-and-pro manner in a direction orthogonal to a direction in which the plural vessels for film forming material are arranged.

Further, it is preferable that the substrate is conveyed at a speed of 1 to 1,000 mm/sec.

Further, it is preferable that the thickness of the stimulable phosphor layer is measured by using plural layer thickness measurement means, and, when the layer thickness measurements obtained by one layer thickness measurement means among the plural layer thickness measurement means is relatively different from layer the thickness measurements obtained by other layer thickness measurement means among the plural layer thickness measurement means, heating of the film forming material in a vessel for film forming material corresponding to the one layer thickness measurement means is controlled differently from heating of the film forming material in other vessels for film forming material corresponding to the other layer thickness measurement means.

Further, it is preferable that plural layer thickness measurement means are arranged in the direction in which the plural vessels for film forming material are arranged.

Further, it is preferable that the thickness of the stimulable phosphor layer is measured by using plural layer thickness measurement means, and heating of the film forming material in each of the plural vessels for film forming material at each position corresponding to each measurement position where the thickness of the stimulable phosphor layer is measured by each of the plural layer thickness measurement means, is controlled based on the layer thickness measurements obtained by using each of the plural layer thickness measurement means, respectively.

Further, it is preferable that the layer thickness measurement means is placed in a vicinity of an end of a conveying region of the substrate in a substrate-conveying direction where the substrate is conveyed in the to-and-fro manner.

Further, it is preferable that the film deposition is performed while the substrate is rotated on its axis, revolved, or revolved while being rotated on its axis.

Further, it is preferable that the substrate is rotated on its axis or revolved at a speed of 1 to 20 rpm.

Furthermore, it is preferable that when the thickness of the stimulable phosphor layer measured by using the layer thickness measurement means reaches a predetermined value, the heating of the film forming material in a vessel for film forming material corresponding to the used layer thickness measurement means is stopped.

According to the method of manufacturing a radiographic image conversion panel of the present invention, the thickness of the stimulable phosphor layer is directly measured during film deposition, using layer thickness measurement means such as a laser displacement sensor. Therefore, the vapor deposition rate is found with a high degree of accuracy, and can be controlled appropriately with a high degree of accuracy. Furthermore, when film deposition (heating with a heating (evaporation) source) should be ended can be determined in accordance with the measurements of the layer thickness, so that the thickness of the stimulable phosphor layer can be controlled with a very high degree of accuracy in combination with the vapor deposition rate controlled with a high degree of accuracy.

Thus, according to the present invention, a high-quality radiographic image conversion panel whose stimulable phosphor layer has an accurate thickness can be manufactured in a consistent manner.

### BRIEF DESCRIPTION OF THE DRAWINGS

In the accompanying drawings:

FIG. 1A is a schematic front view showing an example of a radiographic image conversion panel manufacturing apparatus in which the radiographic image conversion panel manufacturing method of the present invention is implemented;

FIG. 1B is a schematic side view of the radiographic image conversion panel manufacturing apparatus shown in FIG. 1A; and

FIG. 2 is a schematic plan view of a heating/evaporating unit of the radiographic image conversion panel manufacturing apparatus shown in FIGS. 1A and 1B.

### DETAILED DESCRIPTION OF THE INVENTION

The method of manufacturing a radiographic image conversion panel according to the present invention will hereinafter be described in detail on the basis of a preferred embodiment shown in the accompanying drawings.

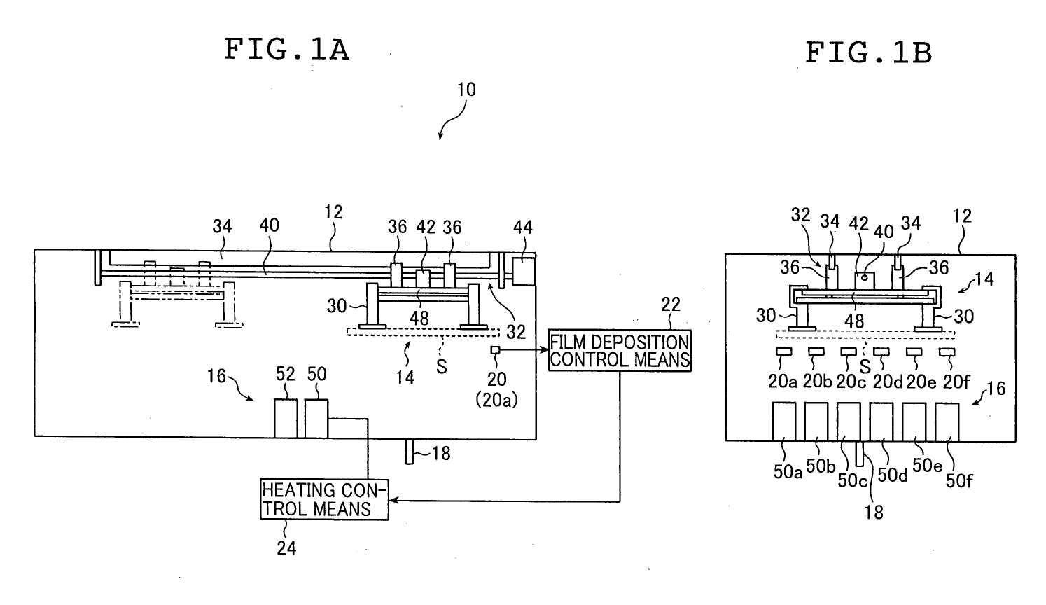

FIGS. 1A and 1B are a front view and a side view conceptually showing an example of a radiographic image conversion panel manufacturing apparatus in which the radiographic image conversion panel manufacturing method of the present invention is implemented.

A radiographic image conversion panel manufacturing apparatus (hereinafter referred to as a “manufacturing apparatus”) 10 shown in FIGS. 1A and 1B is an apparatus for manufacturing a radiographic image conversion panel (hereinafter referred to simply as a “conversion panel”) by forming on the surface of a substrate S a layer made of a stimulable phosphor (hereinafter referred to simply as a “phosphor layer”) through vacuum evaporation.

The manufacturing apparatus 10 basically includes a vacuum chamber 12, a substrate retaining/conveying mechanism 14, a heating/evaporating unit 16, a gas introducing nozzle 18, laser displacement sensors 20 (20a to 20f), film deposition control means 22 and heating control means 24.

It goes without saying that, apart from these components, the manufacturing apparatus 10 of the present invention may include as required various components with which a well-known vacuum evaporation apparatus is equipped, as exemplified by a shutter for blocking out vapor of film forming materials generated in the heating/evaporating unit 16 and a plasma generator (ion gun).

Various materials can be used in the present invention for the stimulable phosphor constituting the phosphor layer. For example, JP 61-72087 A preferably discloses alkali halide-based stimulable phosphors represented by the general formula “M^{I}X·aM^{II}X′₂·bM^{III}X″₃:cA″. In this formula, M^{I} represents at least one element selected from the group consisting of Li, Na, K, Rb, and Cs. M^{II} represents at least one divalent metal selected from the group consisting of Be, Mg, Ca, Sr, Ba, Zn, Cd, Cu, and Ni. M^{III} represents at least one trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one element selected from the group consisting of F, Cl, Br, and I. A represents at least one element selected from the group consisting of Eu, Tb, Ce, Tm, Dy, Pr, Ho, Nd, Yb, Er, Gd, Lu, Sm, Y, Tl, Na, Ag, Cu, Bi, and Mg. a satisfies a relationship of 0≦a<0.5, b satisfies a relationship of 0≦b<0.5, and c satisfies a relationship of 0≦c<0.2.

Further, preferable stimulable phosphors other than those described above are disclosed in U.S. Pat. No. 3,859,527, JP 55-012142 A, JP 55-012144 A, JP 55-012145 A, JP 57-148285 A, JP 56-116777 A, JP 58-069281 A, and JP 59-075200 A.

In particular, the alkali halide-based stimulable phosphors represented by the general formula “M^{I}X·aM^{II}X′₂·bM^{III}X−₃:cA” are preferred in terms of the photostimulated luminescence characteristics, sharpness of reproduced images, the ability to suitably achieve the effects of the present invention, and the like. Of those, the alkali halide-based stimulable phosphors represented by the above formula in which M^{I} contains at least Cs, X contains at least Br, and A is Eu or Bi are more preferred. Of those, the stimulable phosphors represented by the general formula “CsBr:Eu” are particularly preferred.

Further, there is no particular limitation on the material of the substrate S and all types of materials for sheet-shaped substrates used in conversion panels such as glass, ceramics, carbon, aluminum, PET (polyethylene terephthalate), PEN (polyethylene naphthalate), and polyamide are available. There is also no particular limitation on the shape of the substrate S.

The vacuum chamber 12 is a well-known vacuum chamber (bell jar or vacuum vessel) used in a vacuum evaporation apparatus and is formed of iron, stainless steel, aluminum, or the like.

The gas introducing nozzle 18 is also a well-known gas introducing means that has (or is connected to) a means for connecting the nozzle 18 to a gas bomb and a gas flow rate adjusting means and is used in a vacuum evaporation apparatus or a sputtering apparatus. The gas introducing nozzle 18 introduces an inert gas such as argon gas or nitrogen gas into the vacuum chamber 12 in order to form a phosphor layer through vacuum evaporation under medium vacuum to be described later.

In a preferred embodiment of the manufacturing method of the present invention, the vacuum chamber 12 is evacuated to a degree of vacuum of about 0.1 to 10 Pa (this degree of vacuum is hereinafter referred to as “medium vacuum”), while introducing argon gas or other inert gas using the gas introducing nozzle 18, and a phosphor layer is formed.

More specifically, the vacuum chamber 12 is first evacuated to a high degree of vacuum prior to starting film formation. Then, the vacuum chamber 12 is evacuated to the medium vacuum, preferably to a degree of vacuum of about 0.5 to 3 Pa while introducing an inert gas such as argon gas through the gas introducing nozzle 18. Film forming materials (cesium bromide and europium bromide) are heated and evaporated in the heating/evaporating unit 16 under the medium vacuum and the substrate S is linearly conveyed by the substrate retaining/conveying mechanism 14 (this movement is hereinafter referred to as “linear conveyance”). A phosphor layer is thus formed on the substrate S through vacuum evaporation.

By forming a phosphor layer on the substrate S under medium vacuum while introducing a gas, a conversion panel that is excellent in the image sharpness and photostimulated luminescence characteristics and in which the phosphor layer has a favorable columnar crystal structure can be manufactured.

A vacuum pump (not shown) is connected to the vacuum chamber 12.

There are no particular limitations regarding the vacuum pump, and various types of vacuum pumps as used in vacuum evaporation apparatuses can be used as long as they help attain the requisite degree of vacuum. Examples of the vacuum pump that can be used include an oil diffusion pump, a cryogenic pump, and a turbo molecular pump; further, as an auxiliary component, it is also possible to use a cryogenic coil or the like in combination. It is to be noted that in the manufacturing apparatus 10 for forming a phosphor layer, it is desirable for the ultimate degree of vacuum in the vacuum chamber 12 to be 8.0×10⁻⁴ Pa or less.

The substrate retaining/conveying mechanism 14 retains the substrate S and conveys it in a to-and-fro manner along the linear conveyance route. The mechanism 14 includes substrate retaining means 30 and conveyance means 32.

The conveyance means 32 is a well-known linear moving mechanism relying on screw drive. In the illustrated case, the conveyance means 32 includes a linear motor guide having guide rails 34 and catching members 36 guided by the guide rails 34, a ball screw having a screw shaft 40 and a nut 42 and a rotary drive source 44 for rotating the screw shaft 40.

On the other hand, the substrate retaining means 30 is a well-known means for retaining a sheet. In the illustrated case, the substrate retaining means 30 has in the upper portion a plate 48 to which the nut 42 of the ball screw and the catching members 36 of the linear motor guide are fixed, and retains the substrate S in the lower end portion. The substrate S may be retained by any known means such as suction or fixation with an instrument.

The substrate retaining means 30 is linearly conveyed by the conveyance means 32 in a predetermined direction (in the horizontal direction in FIG. 1A and in the direction perpendicular to the paper plane in FIG. 1B).

In the illustrated manufacturing apparatus 10, the substrate retaining means 30 is conveyed by the conveyance means 32 in a to-and-fro manner while retaining the substrate S, whereby the substrate S is linearly conveyed in the predetermined direction.

As will be described later in detail, the manufacturing apparatus 10 linearly conveys the substrate S in a to-and-fro manner and includes vessels for film forming materials (crucibles 50 and 52 serving as resistance heating sources in the illustrated case) that are arranged in the direction perpendicular to the conveyance direction. A phosphor layer which is highly uniform in the layer thickness distribution can be thus formed.

The number of times the substrate S is conveyed in a to-and-fro manner may be determined as appropriate based on the desired thickness of the phosphor layer, the desired uniformity in layer thickness distribution, or the like. If the layer thickness is the same, as the number of times the substrate S passes over the heating/evaporating unit 16 or the substrate S is conveyed in a to-and-fro manner is increased, the uniformity in the layer thickness distribution can be more enhanced.

The conveyance speed is not limited in any particular way and may be determined as appropriate based on the limit conveyance speed in the apparatus, the number of times the substrate S is moved in a to-and-fro manner, the desired thickness of the phosphor layer, etc. The conveyance speed is preferably 1 to 1,000 mm/s taking into account the uniformity in the thickness distribution of the phosphor layer, controllability, load on the substrate retaining/conveying mechanism 14 or other factors.

The laser displacement sensors 20 that are connected to the film deposition control means 22 are disposed in the vicinity of an end of the region where the substrate S is conveyed by the substrate retaining/conveying mechanism 14. These components will be described later in further detail.

In the lower portion of the vacuum chamber 12, there is disposed the heating/evaporating unit 16.

The heating/evaporating unit 16 is the unit for evaporating film forming materials by resistance heating. A shutter (not shown) for blocking out vapor of the film forming materials generated in the heating/evaporating unit 16 (crucibles 50 and 52) is disposed above the heating/evaporating unit 16.

In the illustrated preferable embodiment, a phosphor layer is formed by two-source vacuum evaporation in which a material (evaporation source) constituting the phosphor (base material) and a material constituting the activator are separately evaporated. More preferably, the conversion panel is manufactured by forming the phosphor layer of “CsBr:Eu” on the substrate S through two-source vacuum evaporation in which cesium bromide (CsBr) as the phosphor component and europium bromide (EuBrₓ (x is generally 2 to 3 and preferably 2)) as the activator component are evaporated separately.

The ratio of activator to phosphor in a stimulable phosphor for example in terms of the molar concentration ratio is approximately 0.0005/1 to 0.01/1, which means that most of the phosphor layer consists of phosphor. Thus, the two-source vacuum evaporation in which the phosphor component and the activator component are separately evaporated under heating enables more appropriate heating control to thereby manufacture a high-quality conversion panel in which the phosphor layer contains an appropriate amount of the activator and which achieves uniform dispersion of the activator in the phosphor layer.

The heating/evaporating unit 16 has the crucibles 50 and 52 for the two-source vacuum evaporation. The crucibles 50 contain a phosphor (cesium bromide) and serves as resistance heating sources. On the other hand, the crucibles 52 contain an activator (europium bromide) and also serves as resistance heating sources.

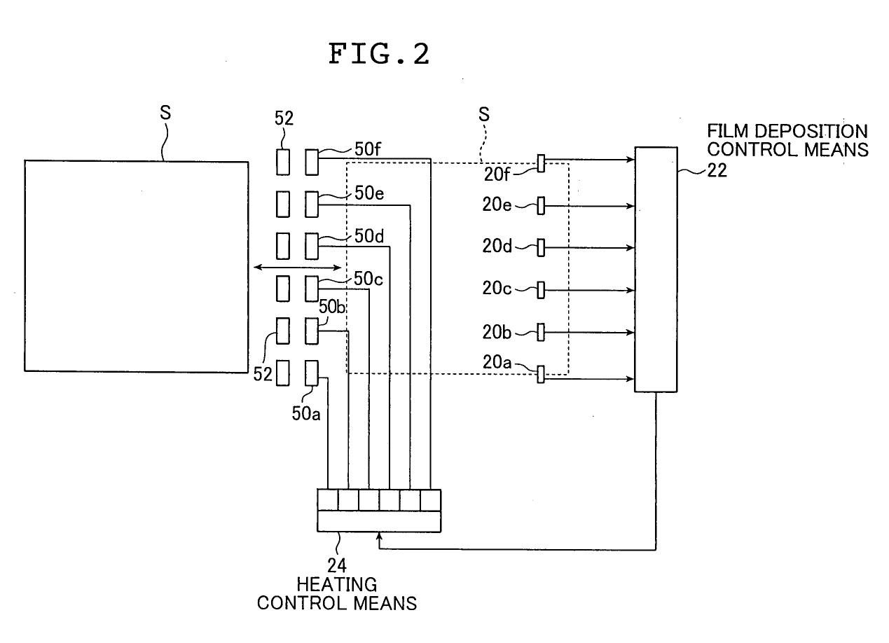

Furthermore, as shown in FIG. 1B and FIG. 2 (schematic plan view), the heating/evaporating unit 16 includes six crucibles 50 (50a to 50f) and six crucibles 52 (52a to 52f). As described above, the phosphor layer formed by vacuum evaporation usually has a thickness of about 500 μm, and in some cases, has a very large thickness of 1,000 μm or more. Furthermore, in the medical application, for example, a conversion panel used for chest radiography is required to have a large surface area. Therefore, by providing a plurality of crucibles (vessels for containing film forming materials), a film with a large surface area and a large thickness can be formed. The number of the crucibles 50 or crucibles 52 is not limited to six. In addition, the number of the crucibles 50 and that of the crucibles 52 are preferably the same, but may be different from each other.

As shown in FIGS. 1B and 2, in the illustrated case, six crucibles 50 and six crucibles 52 are arranged in a direction orthogonal to the direction in which the substrate S is conveyed (hereinafter referred to as a conveyance direction). The respective crucibles are insulated from each other by, for example, placing them at a distance or inserting an insulating material therebetween.

In the manufacturing apparatus 10 in the illustrated case, the substrate S is linearly conveyed as described above, and the crucibles 50 and 52 for resistance heating/evaporation are arranged in a direction orthogonal to the conveyance direction, whereby the entire surface of the substrate S is exposed uniformly to vapor of film forming materials, and a phosphor layer which is highly uniform in layer thickness distribution can be formed.

More specifically, by forming a phosphor layer by vacuum evaporation while conveying the substrate S linearly, the movement speed on the surface (surface on which a film is to be formed) of the substrate S can be made uniform entirely. Therefore, only with the very simple arrangement of evaporation sources in which crucibles (vessels containing film forming materials) are arranged linearly in a direction orthogonal to the conveyance direction, the entire surface of the substrate S can be exposed to vapor of film forming materials uniformly, and a phosphor layer which is highly uniform in layer thickness distribution can be formed.

In particular, in the above-mentioned vacuum evaporation under medium vacuum as described above, particles of a gas such as argon collide with evaporated film forming materials, and the evaporated film forming materials do not ascend to a high level. Thus, compared with commonly performed vacuum evaporation under high vacuum, it is required for the distance between the substrate S and the crucibles to be reduced, and consequently, the film forming materials reach the substrate S before diffusing in a system. Therefore, in the vacuum evaporation under medium vacuum, the configuration in which vacuum evaporation is performed by arranging crucibles in a direction orthogonal to the conveyance direction and linearly conveying the substrate S greatly contributes to the uniformity in the layer thickness distribution. Furthermore, owing to the configuration, an activator component can be dispersed highly uniformly in the stimulable phosphor layer in the plane direction and thickness direction of a phosphor layer. This enables a conversion panel which is excellent in photostimulated luminescence characteristics and is highly uniform in sensitivity and the like to be obtained.

The crucibles 50 and 52 are both formed of a high-melting-point metal such as tantalum (Ta), molybdenum (Mo), or tungsten (W), and generate heat on their own by being energized by an electrode (not shown), thereby heating/melting the film forming materials filled therein and evaporating them.

There is no particular limit to the crucibles 50 and 52. Any known crucible which contains a film forming material (evaporation source), generates heat by being energized, and is used as a resistance heating source in vacuum evaporation by resistance heating is available.

As shown in FIG. 2, the crucibles 50a to 50f are connected to the heating control means 24 having resistance heating power sources respectively corresponding to the crucibles 50a to 50f. The heating control means 24 will be described in detail later.

Furthermore, although not shown for the simplicity of the figure and the clarity of the configuration, each crucible 52 is connected to a resistance heating power source, and is controlled by the heating control means 24. As described above, the vapor deposition amount (evaporation amount) of the activator is small, so that heating is controlled for example by constant current control. The method of controlling the heating of the crucibles 52 is not limited thereto. Various systems used in vacuum evaporation by resistance heating, such as a thyristor system, a DC system, and a thermocouple feedback system, can be used.

In the manufacturing method of the present invention, the method of heating film forming materials (heating sources) is not limited to the resistance heating in the illustrated case, and various kinds of heating/evaporating methods used in vacuum evaporation, such as induction heating and heating with an electron beam (electron gun), can be used.

As described above, the laser displacement sensors 20a-20f are placed in the vicinity of an end of the region where the substrate S is conveyed by the substrate retaining/conveying mechanism 14.

In the illustrated case, the laser displacement sensors 20a-20f are layer thickness measurement means with which a downward displacement of the surface of the phosphor layer (substrate S) is detected during formation of the phosphor layer to measure the thickness of the phosphor layer formed on the substrate S. In other words, the laser displacement sensors 20a-20f each detect a displacement of the surface of the phosphor layer in a thickness direction of the phosphor layer to measure the thickness of the phosphor layer formed on the substrate S.

In the illustrated case, one laser displacement sensor 20 is preferably placed per crucible 50 for a phosphor, whereby the displacement at a corresponding position is detected.

More specifically, the laser displacement sensor 20a mainly detects a displacement of the surface of the substrate S at a position where the film forming material from the crucible 50a is deposited. The laser displacement sensor 20b mainly detects a displacement of the surface of the substrate S at a position where the film forming material from the crucible 50b is deposited. The laser displacement sensor 20f mainly detects a displacement of the surface of the substrate S at a position where the film forming material from the crucible 50f is deposited.

In the present invention, the layer thickness measurement means is not limited to the laser displacement sensor 20, and for example, various kinds of means such as an electrostatic capacitance displacement sensor can be used. In the case of using the electrostatic capacitance displacement sensor, the displacement may be measured for example by inverse operation from the dielectric constant of a stimulable phosphor.

The detection results of the displacement of the surface of the substrate S (i.e., the surface of a phosphor layer) obtained by using each laser displacement sensor 20 are sent to the film deposition control means 22.

The film deposition control means 22 detects the layer thickness and vapor deposition rate of the phosphor layer at a position corresponding to each laser displacement sensor 20 based on the detection results obtained by each laser displacement sensor 20. Furthermore, the film deposition control means 22 gives an instruction for controlling the heating temperature of each crucible 50 to the heating control means 24 in accordance with the detected layer thickness and vapor deposition rate. The detection results obtained by the laser displacement sensor 20a correspond to the temperature control of the crucible 50a, the detection results obtained by the laser displacement sensor 20b correspond to the temperature control of the crucible 50b, . . . the detection results obtained by the laser displacement sensor 20f correspond to the temperature control of the crucible 50f.

The heating control means 24 has a resistance heating power source corresponding to each crucible 50 (and a resistance heating power source corresponding to each crucible 52). The heating control means 24 controls the output of the corresponding resistance heating power source in accordance with an instruction for controlling the heating temperature of each crucible 50 as supplied from the film deposition control means 22, and adjusts the heat generation (i.e., heating of the film forming material) for each crucible 50, thereby controlling the vapor deposition rate (evaporation amount of the film forming material) in each crucible 50.

More specifically, based on the results of the displacement of the surface of the phosphor layer as detected by the laser displacement sensor 20, the film deposition control means 22 detects the layer thickness of the phosphor during film deposition and its variation for each position at which each laser displacement sensor 20 performs measurement and differentiates the change in layer thickness with respect to the time to calculate the vapor deposition rate.

Furthermore, in accordance with the calculated vapor deposition rate, the film deposition control means 22 instructs the heating control means 24 to maintain the current situation in the case where the calculated vapor deposition rate is appropriate. Furthermore, in the case where the calculated vapor deposition rate is too high, the film deposition control means 22 instructs the heating control means 24 to lower the heating temperature of the corresponding crucible 50. Furthermore, in the case where the calculated vapor deposition rate is too low, the film deposition control means 22 instructs the heating control means 24 to raise the heating temperature of the corresponding crucible 50.

As an example, in the film deposition control means 22, a previously prepared look-up table (LUT) for giving a relationship between the vapor deposition rate and the heating temperature is set. The film deposition control means 22 calculates the vapor deposition rate for each laser displacement sensor 20, detects a corresponding heating temperature from the calculated vapor deposition rate for each crucible 50, using the LUT, and supplies the heating temperature to the heating control means 24. Alternatively, the heating temperature may be calculated using a previously prepared arithmetic expression in place of the LUT.

Furthermore, upon detection of a position where the layer thickness is relatively different from those of the other positions from the detection results obtained by the respective laser displacement sensors 20a-20f, the film deposition control means 22 gives an instruction to the heating control means 24 so that the corresponding crucible 50 and the other crucibles 50 are controlled for their heating temperature in a different manner.

For example, in the case where the layer thickness measured by the laser displacement sensor 20a becomes relatively larger than in the other regions, the film deposition control means 22 instructs the heating control means 24 to lower the temperature of the crucible 50a and/or raise the temperature of each of the crucibles 50b to 50f. In contrast, in the case where the layer thickness measured by the laser displacement sensor 20a becomes relatively smaller than in the other regions, the film deposition control means 22 instructs the heating control means 24 to lower the temperature of each of the crucibles 50b to 50f and/or raise the temperature of the crucible 50a.

Furthermore, when it is detected from the measurements obtained by the laser displacement sensors 20a-20f that the phosphor layer has a predetermined thickness, the film deposition control means 22 instructs the heating control means 24 to stop the heating of the corresponding crucible 50 and the crucible 52 arranged adjacent to the crucible 50 in the conveyance direction.

The heating control means 24 having received an instruction for controlling the heating temperature controls for each crucible 50 the output of a corresponding resistance heating power source in accordance with the received instruction for temperature control to adjust the heat generation of each crucible 50, thereby controlling the vapor deposition rate in each crucible 50.

Furthermore, when an instruction for stopping the heating of a crucible 50 is received, the supply of power from the corresponding resistance heating power source to the crucible 50 and the crucible 52 concerned is stopped.

As is apparent from the above description, according to the method of manufacturing a radiographic image conversion panel of the present invention, the thickness of the phosphor layer is directly measured during film deposition using the layer thickness measurement means such as the laser displacement sensors, the vapor deposition rate is detected using the results, the heating, i.e., the vapor deposition rate of each crucible 50 is controlled, and the completion of vapor deposition is determined.

Thus, even in a vapor deposition layer having a very large layer thickness and having a columnar crystal structure with pores as in the phosphor layer, the vapor deposition rate can be found with a very high degree of accuracy and thus controlled compared with a conventional method in which the vapor deposition rate was controlled by presuming it using the evaporation amount, optical characteristics, and the like. As a result, film deposition at a constant vapor deposition rate can be performed to form a phosphor layer which has a preferable columnar structure, is highly uniform in the activator distribution, and has an appropriate layer thickness.

Furthermore, the vapor deposition can be stopped at a time when a predetermined layer thickness is obtained, so that the control of the layer thickness can also be performed with a higher degree of accuracy in combination with the vapor deposition rate controlled with a high degree of accuracy. In particular, as in the illustrated system having multiple crucibles, the layer thickness can be detected at the position corresponding to each crucible, and the vapor deposition can be stopped for each crucible. Therefore, the phosphor layer formed can be excellent in uniformity of layer thickness and have a highly accurate thickness.

More specifically, according to the present invention, a high-quality (radiographic image) conversion panel having a phosphor layer with a highly accurate thickness and with a satisfactory crystal structure or the like can be manufactured consistently by vacuum evaporation in which the vapor deposition rate is controlled with a high degree of accuracy.

When vacuum evaporation is performed by conveying the substrate S linearly in a to-and-fro manner as in the illustrated case, the layer thickness measurement means such as the laser displacement sensor can be placed at a position away from the evaporation position (resistance heating source) of a film forming material, i.e., at a position where vapor of the film forming material is hardly present. Therefore, measurement of the layer thickness can be performed with a high degree of accuracy without being adversely affected by vapor or the like. Further, a hindrance to vapor deposition by the layer thickness measurement means or the like, and deposition of film forming materials onto the layer thickness measurement means can also be avoided by performing vacuum evaporation while the substrate is conveyed in a to-and-for manner, which further ensures a high degree of freedom for the position at which the layer thickness measurement means is arranged and also facilitates the apparatus design.

Furthermore, with the simple arrangement in which the layer thickness measurement means are linearly arranged, the layer thickness can be detected over the entire region in a direction orthogonal to the conveyance direction of the substrate S. As described above, in the to-and-fro linear conveyance, the uniformity of the layer thickness is very high in the conveyance direction. Thus, by detecting the layer thickness at one position in the conveyance direction, the layer thickness can be detected over the entire region thereof with a high degree of accuracy. In other words, the layer thickness of the phosphor layer over the entire region of the conversion panel can be measured.

Furthermore, the position at which the layer thickness detection means is arranged and the region where the substrate S is conveyed are set as appropriate, whereby the thickness of the phosphor layer can be directly measured over the entire surface of the substrate S. Furthermore, the layer thickness may be detected at two portions sandwiching the crucibles in the conveyance direction, whereby the thickness of the phosphor layer can be detected more suitably, and even in the case of detecting the layer thickness over the entire surface, the conveyance distance of the substrate can be reduced.

As described above, the amount of the activator deposited is much smaller than that of the phosphor deposited. Therefore, by merely controlling the heating of the crucibles 50 (i.e., the phosphor component) variably while controlling the crucibles 52 with a constant current, the vapor deposition rate can be appropriately controlled. However, it should be appreciated that the heating control of the crucibles 52 may be performed based on the detection results obtained by the laser displacement sensor 20.

In the above case, each crucible 50 is preferably provided with one laser displacement sensor 20 so that the heating is controlled based on the measurements obtained by the laser displacement sensor 20 corresponding to each crucible 50. With such a configuration, indeterminate factors such as the variation in the evaporation state caused by the change in the amount of the remaining film forming material are excluded, and the vapor deposition rate and the layer thickness can be controlled with a higher degree of accuracy.

However, the present invention is not limited thereto. The vapor deposition rate, the vapor deposition stop, and the like in two, three or more crucibles 50 may be controlled based on the detection results obtained by one layer thickness detection means.

The apparatus in the illustrated case performs vacuum evaporation while linearly conveying the substrate S in a to-and-fro manner. However, the present invention is not limited thereto. The apparatus may be of a so-called substrate rotation type in which vacuum evaporation is performed while the substrate S is rotated.

In the case of the substrate rotation type, the substrate S may be rotated on its axis, revolved, or revolved while being rotated on its axis. There is no particular limit to the rotation speed of the substrate S but it is preferable that the rotation speed be about 1 to 20 rpm in terms of the uniformity in film thickness in both of the rotation on its axis and revolution.

Even when film deposition is performed while the substrate is rotated, two-source vacuum evaporation in which an activator and a phosphor are heated and evaporated with separate crucibles is preferable. Furthermore, in order to allow a film having a large surface area and a large thickness to be deposited, it is preferable that a phosphor and an activator be heated and evaporated with more than one crucible. It is also preferable that each crucible for the phosphor be provided with one layer thickness measurement means.

In the following, an example of the operation for manufacturing a conversion panel by the manufacturing apparatus 10 will be described.

First, the vacuum chamber 12 is opened, and the substrate S is retained by the retaining means 30. All the crucibles 50 and 52 are filled with cesium bromide and europium bromide to predetermined amounts, respectively. Thereafter, the shutter above the heating/evaporating unit 16 is closed, and the vacuum chamber 12 is closed.

Subsequently, a vacuum evacuating means is driven to evacuate the vacuum chamber 12. When the internal pressure of the vacuum chamber 12 reaches, for example, 8×10⁻⁴ Pa, argon gas is introduced through the gas introducing nozzle 18 into the vacuum chamber 12, which is continuously evacuated to thereby adjust the internal pressure of the vacuum chamber 12 to, for example, 1 Pa. Further, the heating control means 24 drives the power sources for resistance heating to energize all the crucibles 50 and 52, thereby heating the film forming materials. When a predetermined period of time has elapsed after the start of the heating of the film forming materials, the rotary drive source 44 is driven to start the conveyance of the substrate S. Subsequently, the shutter is opened to start the formation of a phosphor layer on the surface of the substrate S.

During the film deposition, the displacement of the surface of the phosphor layer is detected by the laser displacement sensors 20a-20f and the detection results are sent to the film deposition control means 22. The film deposition control means 22 uses the detection results obtained by the laser displacement sensors 20a-20f to calculate the layer thickness and vapor deposition rate for each position at which detection was made by each of the laser displacement sensors 20a-20f, determines to control the heating temperature of each crucible 50 based on the calculation results and sends a control instruction to the heating control means 24. The heating control means 24 controls the power supply for resistance heating to each crucible 50 in accordance with the instruction for controlling the heating temperature and keeps the vapor deposition rate proper.

Upon detection of a portion having a larger thickness than the predetermined layer thickness, the film deposition control means 22 instructs the heating control means 24 to stop heating the crucibles 50 corresponding to the detected portion. The heating control means 24 stops power supply for resistance heating to the corresponding crucibles 50 and 52 in accordance with the given instruction.

When heating of all the crucibles is thus stopped, the linear conveyance of the substrate S is stopped and the shutter is closed. The amount of argon gas introduced through the gas introducing nozzle 18 is increased to adjust the internal pressure of the vacuum chamber 12 to atmospheric pressure. Then, the vacuum chamber 12 is opened and the substrate S having a phosphor layer formed thereon, that is, the conversion panel manufactured is taken out of the chamber.

The conversion panel is a high-quality panel that has a phosphor layer which is formed at a proper vapor deposition rate, has a favorable columnar crystal structure, is uniform in the activator distribution, and has a highly accurate layer thickness.

While the method of manufacturing a radiographic image conversion panel according to the present invention has been described above in detail, the present invention is by no means limited to the foregoing embodiment and various improvements and modifications may of course be made without departing from the scope and spirit of the invention.

The above-mentioned preferable embodiment is directed to the two-source vacuum evaporation in which the activator and the phosphor are evaporated in separate crucibles under heating. However, this is not the sole case of the present invention and the manufacturing apparatus may be a one-source vacuum evaporation apparatus in which all the film forming materials are mixed together and put in an evaporation source to perform one-source vacuum evaporation. Alternatively, the manufacturing apparatus may be an apparatus in which three or more kinds of film forming materials are contained in different crucibles and evaporated under heating to perform three or more-source vacuum evaporation.

In the illustrated preferable embodiment, more than one crucible is provided for each film forming material. However, this is not the sole case of the present invention and one crucible may be provided for each film forming material. An alternative form is also possible in which only one crucible is provided for one or each of some film forming materials and more than one crucible for others.

What is claimed is:

1. A method of manufacturing a radiation image conversion panel, comprising:
forming a stimulable phosphor layer on a substrate by performing film deposition through vacuum evaporation;
measuring a thickness of the stimulable phosphor layer during the film deposition with layer thickness measurement means to obtain layer thickness measurements; and
controlling heating of film forming material based on the thus obtained layer thickness measurements.

2. The method of manufacturing a radiation image conversion panel according to claim 1, wherein the layer thickness measurement means comprises a laser displacement sensor.

3. The method of manufacturing a radiation image conversion panel according to claim 1, wherein the layer thickness measurements measured by the layer thickness measurement means is differentiated with respect to time to calculate a vacuum evaporation rate, and then the heating of the film forming material is controlled using the thus calculated vacuum evaporation rate.

4. The method of manufacturing a radiation image conversion panel according to claim 3, wherein a look-up table representing a relationship between heating temperatures and vacuum evaporation rates is previously prepared, a heating temperature is determined from the calculated vacuum evaporation rate using the thus prepared look-up table, and the heating of the film forming material is controlled in accordance with the thus determined heating temperature.

5. The method of manufacturing a radiation image conversion panel according to claim 1, wherein the film deposition through the vacuum evaporation is performed by containing the film forming material in plural vessels for film forming material.

6. The method of manufacturing a radiation image conversion panel according to claim 5, wherein the film forming material comprises a base film forming material constituting a base component of a stimulable phosphor and an activator film forming material constituting an activator component of the stimulable phosphor, the plural vessels include at least one first vessel which contains the base film forming material and at least one second vessel which contains the activator film forming material, and the base film forming material contained in said at least one first vessel and the activator film forming material contained in said at least one second vessel are heated and evaporated.

7. The method of manufacturing a radiation image conversion panel according to claim 1, wherein the thickness of the stimulable phosphor layer is measured by using plural layer thickness measurement means.

8. The method of manufacturing a radiation image conversion panel according to claim 7, wherein the heating of the film forming material in one vessel for film forming material is controlled based on thickness measurements obtained by one of the plural layer thickness measurement means.

9. The method of manufacturing a radiation image conversion panel according to claim 5, wherein the plural vessels for film forming material are arranged in one direction, and the film deposition is performed while the substrate is linearly conveyed in a to-and-pro manner in a direction orthogonal to a direction in which the plural vessels for film forming material are arranged.

10. The method of manufacturing a radiation image conversion panel according to claim 9, wherein the substrate is conveyed at a speed of 1 to 1,000 mm/sec.

11. The method of manufacturing a radiation image conversion panel according to claim 9, wherein the thickness of the stimulable phosphor layer is measured by using plural layer thickness measurement means, and wherein, when the layer thickness measurements obtained by one layer thickness measurement means among the plural layer thickness measurement means is relatively different from layer the thickness measurements obtained by other layer thickness measurement means among the plural layer thickness measurement means, heating of the film forming material in a vessel for film forming material corresponding to the one layer thickness measurement means is controlled differently from heating of the film forming material in other vessels for film forming material corresponding to the other layer thickness measurement means.

12. The method of manufacturing a radiation image conversion panel according to claim 9, wherein plural layer thickness measurement means are arranged in the direction in which the plural vessels for film forming material are arranged.

13. The method of manufacturing a radiation image conversion panel according to claim 9, wherein the thickness of the stimulable phosphor layer is measured by using plural layer thickness measurement means, and wherein heating of the film forming material in each of the plural vessels for film forming material at each position corresponding to each measurement position where the thickness of the stimulable phosphor layer is measured by each of the plural layer thickness measurement means, is controlled based on the layer thickness measurements obtained by using each of the plural layer thickness measurement means, respectively.

14. The method of manufacturing a radiation image conversion panel according to claim 9, wherein the layer thickness measurement means is placed in a vicinity of an end of a conveying region of the substrate in a substrate-conveying direction where the substrate is conveyed in the to-and-fro manner.

15. The method of manufacturing a radiation image conversion panel according to claim 1, wherein the film deposition is performed while the substrate is rotated on its axis, revolved, or revolved while being rotated on its axis.

16. The method of manufacturing a radiation image conversion panel according to claim 15, wherein the substrate is rotated on its axis or revolved at a speed of 1 to 20 rpm.

17. The method of manufacturing a radiation image conversion panel according to claim 1, wherein, when the thickness of the stimulable phosphor layer measured by using the layer thickness measurement means reaches a predetermined value, the heating of the film forming material in a vessel for film forming material corresponding to the used layer thickness measurement means is stopped.
